(19) United States
(12) Patent Application Publication
(10) Pub. No.: US 2026/0107818 A1
(43) Pub. Date: Apr. 16, 2026

(54) COPPER INTERCONNECT STRUCTURE AND METHOD FOR FABRICATING THE SAME

(71) Applicant: Chengdu Monolithic Power Systems Co., Ltd., Chengdu (CN)

(72) Inventors: Jiyan Peng, Chengdu (CN); Zeqiang Yao, Kirkland, WA (US); Heng Li, Chengdu (CN); Bin Li, Chengdu (CN); Yan Chen, Chengdu (CN)

(21) Appl. No.: 19/340,590

(22) Filed: Sep. 25, 2025

(30) Foreign Application Priority Data
Oct. 16, 2024 (CN) 202411443881.4

(51) Int. Cl. H01L 23/00

(52) U.S. Cl. CPC H10W 72/90; H10W 72/019; H10W 72/075; H10W 72/50; H10W 72/01935; H10W 72/07532; H10W 72/5524; H10W 72/923; H10W 72/952

(57) ABSTRACT

A copper interconnect structure for an integrated circuit chip is provided for forming a good electrical solder connection with a large-sized metal wire easily. The copper interconnect structure includes a copper surface, a metal barrier layer, and a weldable metal layer. The weldable metal layer is formed with a thickness ranging from 0.03 micrometers to 0.05 micrometers over the metal barrier layer.

### REFERENCE TO RELATED APPLICATIONS

This application claims priority to and the benefit of Chinese Patent Application No. 202411443881.4, filed on Oct. 16, 2024, which is incorporated herein by reference in its entirety.

### FIELD OF INVENTION

The present disclosure relates to copper interconnect structure and methods for fabricating the same.

### BACKGROUND

In the trend of miniaturization of modern integrated circuit (IC) chips, aluminum interconnect structures, which have relatively high resistivity and are used to provide electrical connection or electrical coupling in IC chips, are gradually replaced by copper interconnect structures with higher conductivity. Copper bonding pads and copper redistribution structures are common interconnect structures in modern ICs. In order to reliably weld metal wires to the welding areas of these copper interconnect structures, technicians have developed mature structures and processes.

However, in some applications, in order to improve the current carrying capacity of metal wires, it is necessary to use metal wires with larger sizes than general metal wires. The huge cost advantage of large-sized aluminum wires compared to copper wires or gold wires of the same size has strongly promoted the research on how to weld large-sized aluminum wires to the welding areas of conventional copper interconnect structures.

Research has found that aluminum materials have good mechanical adhesion and are suitable for pressure welding. However, copper materials have poor pressure welding performance, and most mature processes are optimization studies on fusion welding processes. Although a few technologies can realize pressure welding of metal wires on copper interconnect structures, the cost is high and does not meet the application requirements of actual IC production and mass production.

### SUMMARY

In some embodiments of the present disclosure, a copper interconnect structure for an integrated circuit chip is provided. The copper interconnect structure has a copper surface, a metal barrier layer over the copper surface, and a weldable metal layer over the metal barrier layer. The weldable metal layer has a thickness ranging from 0.03 micrometers to 0.05 micrometers.

In some embodiments of the present disclosure, a bonding structure including a copper interconnect structure for an integrated circuit is provided. The bonding structure includes a copper surface, a metal barrier layer over the copper surface, a weldable metal layer over the metal barrier layer, and a metal wire bonded to the weldable metal layer. The metal wire has a diameter equal to or greater than 125 micrometers.

In some embodiments of the present disclosure, a method for fabricating a copper interconnect structure for an integrated circuit chip is provided. The method includes cleaning a copper surface of a non-oxidized copper; performing a first electroless deposition process to plate a metal barrier layer over the copper surface; and performing a second electroless deposition process to plate a weldable metal layer over the metal barrier layer, wherein the weldable metal layer has a thickness ranging from 0.03 micrometers to 0.05 micrometers.

In some embodiments of the present disclosure, a method for bonding a copper interconnect structure of an integrated circuit chip and a metal wire, the method comprising cleaning a copper surface of a non-oxidized copper; performing a first electroless deposition process to plate a metal barrier layer over the copper surface; performing a second electroless deposition process to plate a weldable metal layer over the metal barrier layer, wherein the weldable metal layer has a thickness ranging from 0.03 micrometers to 0.05 micrometers; and bonding the metal wire onto the weldable metal layer by pressure welding, wherein the metal wire has a diameter equal to or greater than 125 micrometers.

In some embodiments of the present disclosure, a method for bonding a copper interconnect structure of an integrated circuit chip and a metal wire, the method comprising: cleaning a copper surface of a non-oxidized copper; performing a first electroless deposition process to plate a metal barrier layer over the copper surface; performing a second electroless deposition process to plate a weldable metal layer over the metal barrier layer, wherein the weldable metal layer has a thickness ranging from 0.03 micrometers to 0.05 micrometers; and bonding the metal wire onto the weldable metal layer by pressure welding, wherein the metal wire has a diameter equal to or greater than 125 micrometers.

In some embodiments of the present disclosure, a copper interconnect structure for an integrated circuit chip is provided. The copper interconnect structure includes a copper pad or a copper redistribution layer, a metal barrier layer over the copper pad or the copper redistribution layer; and a weldable metal layer over the metal barrier layer. The weldable metal layer has a thickness ranging from 0.03 micrometers to 0.05 micrometers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a copper interconnect structure according to an embodiment of the present disclosure, which also shows a metal wire bonded to the copper interconnect structure.

FIG. 2 is a cross-sectional view of a copper interconnect structure according to an embodiment of the present disclosure, which also shows a metal wire bonded to the copper interconnect structure.

FIG. 3 is a comparative example, showing another copper interconnect structure that does not adopt the solution of the present disclosure, and also showing a metal wire bonded thereto.

FIG. 4 shows a method for forming a copper interconnect structure according to some embodiments of the present disclosure.

FIG. 5 shows a method for bonding a copper interconnect structure and a metal wire according to some embodiments of the present disclosure.

FIG. 6 shows a Scanning Electron Microscope (SEM) image of a comparative example sample.

FIG. 7 shows a SEM image of a sample of the copper interconnect structure according to some embodiments of the present disclosure.

### DETAILED DESCRIPTION

The specific embodiments of the present disclosure will be described in detail below. It should be noted that the embodiments described herein are only for illustration and are not intended to limit the present disclosure. In the following description, a large number of specific details are set forth in order to provide a thorough understanding of the present invention. However, it is obvious to those of ordinary skill in the art that these specific details do not have to be adopted to implement the present invention. In other examples, in order to avoid confusing the key points of the present invention, known processes and structures are not specifically described.

Throughout the specification and claims, the phrases “in one embodiment”, “in some embodiments”, “in one example”, and “in some examples” mean that the specific features, structures or characteristics described in conjunction with the embodiment or example are included in at least one embodiment of the present disclosure. Therefore, the phrases “in one embodiment”, “in some embodiments”, “in one example”, and “in some examples” appearing in various places throughout the specification do not necessarily refer to the same embodiment or example. When describing a layer as being disposed on another layer or on a surface in this disclosure, it may be disposed directly on the layer or on the surface, or may include a situation where other material layers are disposed between the two. In addition, it should be understood by those of ordinary skill in the art that the drawings provided herein are for illustrative purposes and the drawings are not necessarily drawn to scale. The same reference numerals indicate the same elements. The term “and/or” as used herein includes any and all combinations of one or more of the related listed items.

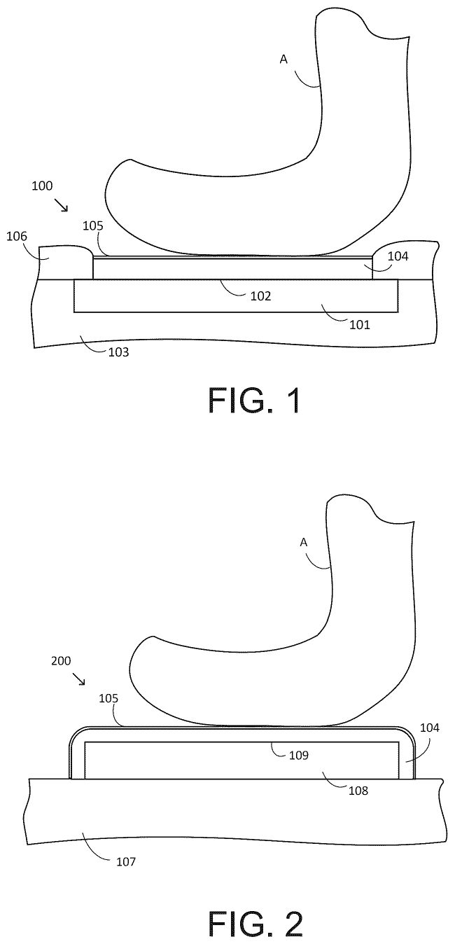

FIG. 1 shows a copper interconnect structure 100 according to an embodiment of the present disclosure, and also shows a metal wire A bonded thereto. In one embodiment, the copper interconnect structure 100 includes a copper pad 101 disposed on a semiconductor substrate 103, the copper pad 101 includes a copper surface 102 for forming a welding area, and the copper surface 102 is exposed by an opening of a protective material 106. FIG. 2 schematically shows another copper interconnect structure 200 according to the present disclosure, which includes a redistribution structure. Generally, the redistribution structure may include plural metal layers disposed in a dielectric layer 107 and an interconnect structure connected to the plural metal layers. The copper redistribution layer 108 shown in FIG. 2 is the outermost layer/topmost layer of the redistribution structure. The copper redistribution layer 108 includes a copper surface 109 for forming a welding area.

The copper surface 102/copper surface 109 are easily oxidized to form a copper oxide film. A copper oxide film, even being very thin, will affect welding, and then affect the reliability of the IC. Therefore, it is necessary to set a metal barrier layer 104 to isolate the copper surface 102/copper surface 109. The reason why it is called a “metal barrier layer” is that it can prevent copper atoms from diffusing to reach the surface of the metal barrier layer 104 and being oxidized into copper oxide there, thereby destroying the welding stability. To achieve this goal, it is necessary to consider the material and thickness of the metal barrier layer 104. In some embodiments, the metal barrier layer 104 is made of a material selected from the group consisting of nickel, cobalt, chromium, molybdenum, tungsten and their alloys. Usually, the barrier layer has a thickness ranging from 0.5 micron to 1.5 micrometers.

In the embodiments of FIG. 1 and FIG. 2, the metal barrier layer 104 is directly disposed on the copper surface 102/copper surface 109. However, in other embodiments, a seed metal layer may be disposed between the copper surface 102/copper surface 109 and the metal barrier layer 104. It should be noted that when the metal barrier layer 104 is disposed on the copper surface 102/copper surface 109 in the present application, it includes both the case where the metal barrier layer 104 is directly disposed on the copper surface 102/copper surface 109 and the case where a seed metal layer is disposed between the metal barrier layer 104 and the copper surface 102/copper surface 109.

In some embodiments, the material of the metal barrier layers 104 has poor weldability, so it is necessary to further set a weldable metal layer 105 thereon. In some embodiments, the material of the weldable metal layer 105 can be gold, platinum, palladium and silver. In the technical solution of the present application, the thickness of the weldable metal layer 105 is in a range from 0.03 micron and 0.05 micron.

In some embodiments, as shown in FIG. 1 and FIG. 2, an aluminum wire A with a diameter equal to or greater than 125 micrometers is bonded to the weldable metal layer 105 of the copper interconnect structure 100/copper interconnect structure 200 by pressure welding. In some other embodiments, aluminum wires with various sizes (e.g., different diameters) are bonded to the weldable metal layer 105 of the copper interconnect structure 100/200 by pressure welding, respectively. For example, the aluminum wires with various sizes may include the aluminum wires having diameters equal to or greater than 170 micrometers, the aluminum wires having diameters equal to or greater than 190 micrometers, the aluminum wires having diameters equal to or greater than 210 micrometers, the aluminum wires having diameters equal to or greater than 230 micrometers, the aluminum wires having diameters equal to or greater than 250 micrometers, the aluminum wires having diameters equal to or greater than 270 micrometers, the aluminum wires having diameters equal to or greater than 300 micrometers, etc. Good solder joints can be formed between the aluminum wire and the copper interconnect structure 100/copper interconnect structure 200, and there is no delamination between the aluminum wire and the copper surface, and the solder joints all show good electrical connection performance. The above experimental results show that the copper interconnect structure provided in the present application is suitable for being bonded with large-sized metal wires than general metal wires. Although large-sized aluminum wires are bonded in the above embodiments, large-sized copper wires, large-sized gold wires and other metal wires can also be bonded in other embodiments. Although the copper interconnect structure provided in the present application has the characteristic of good bonding with large-sized metal wires, it does not limit its application to be bonded with conventional-sized metal wires. In fact, in some embodiments, bonding a metal wire with a diameter less than 125 micrometers onto the weldable metal layer 105 of the copper interconnect structure 100 by pressure welding can also obtain a solder joint with good electrical connection performance.

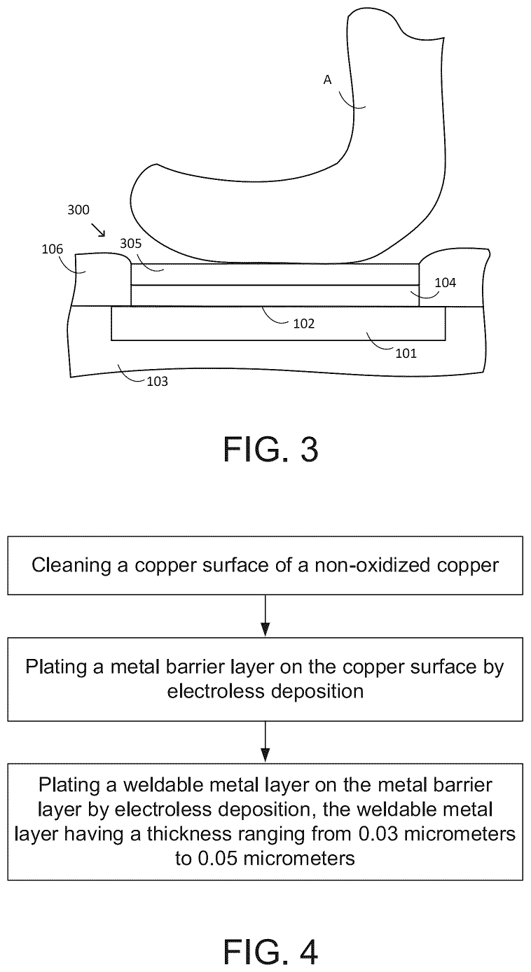

FIG. 3 is a comparative example, which shows another copper interconnect structure 300 that does not adopt the disclosed solution. The copper interconnect structure 300 shown in the comparative example has many same configurations as the copper interconnect structure 100/200 disclosed in the present application, and FIG. 3 uses the same reference numerals as FIG. 1 to represent these same features. The difference is that the copper interconnect structure 300 includes a weldable metal layer 305 disposed on the barrier metal layer 104. The material of the weldable metal layer 305 can be gold, platinum, palladium and silver. In some comparative examples, the thickness of the weldable metal layer 305 is in a range from 0.4 micrometers to 1.5 micrometers. In these comparative examples, an aluminum metal wire A having a diameter equal to or greater than 125 micrometers is bonded on the copper interconnect structures 300 by pressure welding, and the conductive performance of the solder joints was tested. The results showed that the electrical connection performance between the copper interconnect structure 300 and the aluminum metal wire A was poor, and the resistance failure rate of the test samples reached 100%.

FIG. 4 shows a method for forming a copper interconnect structure according to an embodiment of the present disclosure. The method includes a preparation step, namely providing a cleaned copper surface without copper oxide. In some processes, it may be necessary to protect the copper surface of the non-welding area, for example, by coating a protective layer on the copper surface of the non-welding area. The protective layer has an opening that exposes the copper surface 102. The wafer including the copper interconnect structure is cleaned with a solution to obtain a clean copper surface without copper oxide.

The method also includes plating a metal barrier layer on the copper surface by electroless deposition. The metal barrier layer is made of a material selected from the group consisting of nickel, cobalt, chromium, molybdenum, tungsten and alloys thereof. In one embodiment, nickel with a thickness of 0.4 micrometers can be electrolessly plated, and in another embodiment, a nickel-tungsten alloy with a thickness of 0.6 micrometers can be electrolessly plated.

In some embodiments, a seed metal layer can also be disposed between the copper surface and the metal barrier layer. It should be clarified that when the metal barrier layer is plated on the copper surface in the present application, it includes both the case of directly plating the metal barrier layer on the copper surface and the case of first providing a seed metal layer and then plating the metal barrier layer on the seed metal layer.

The method further includes plating a weldable metal layer on the metal barrier layer by electroless deposition. The weldable metal layer is made of a material selected from the group consisted of gold, palladium, silver and platinum. The weldable metal layer has a thickness ranging from 0.03 micrometers to 0.05 micrometers. In one embodiment, gold with a thickness of 0.05 micrometers is plated on the metal barrier layer, and in another embodiment, gold-palladium alloy with a thickness of 0.03 micrometers is plated on the metal barrier layer.

The above steps are the core steps for forming the copper interconnect structure described in the present application. The copper interconnect structure formed according to the method has advantage of forming a good bond with a large-sized metal wire. However, it does not limit the present disclosure. The copper interconnect structure formed according to the method can be used to form a bond with a conventional-sized metal wire.

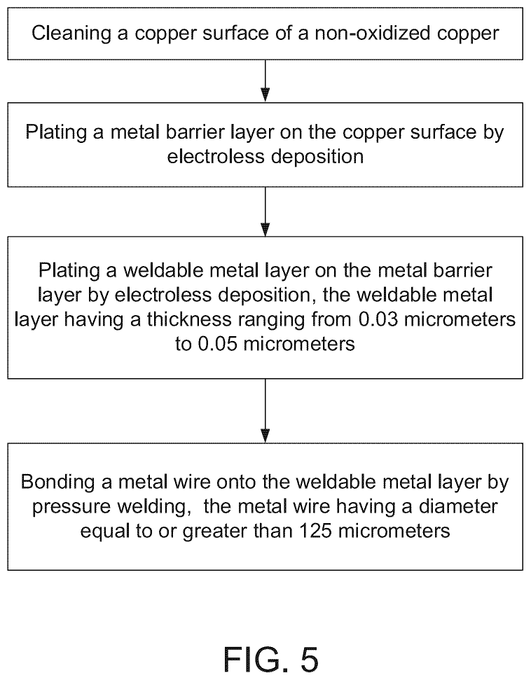

In some embodiments, the copper interconnect structure is used for bonding with a large-sized metal wire. As shown in FIG. 5, the method for forming such a bonding structure further includes bonding a metal wire onto the weldable metal layer by pressure welding (e.g., press-welded), and the diameter of the metal wire is equal to or greater than 125 micrometers. For example, in one embodiment, an aluminum metal wire having a diameter equal to or greater than 170 micrometers can be bonded onto the weldable metal layer by pressure welding, and in another embodiment, an aluminum alloy metal wire having a diameter equal to or greater than 190 micrometers can be bonded onto the weldable metal layer by pressure welding.

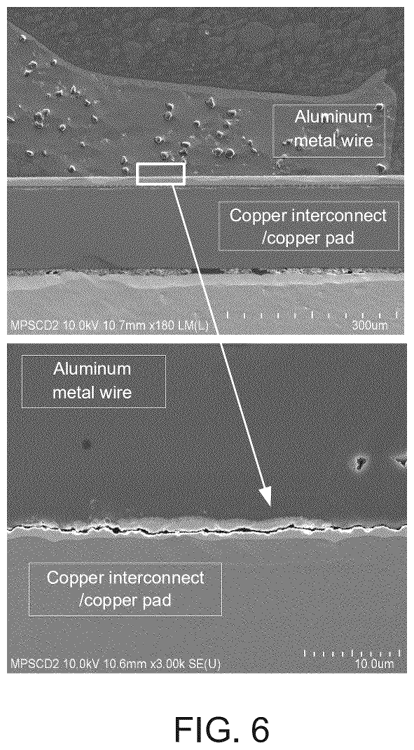

The present application provides a copper interconnect structure that is easy to form a good solder joint with a large-sized metal wire. The copper interconnect structure can be obtained by forming a metal barrier layer on the copper surface and providing a weldable metal layer with a thickness ranging from 0.03 micrometers to 0.05 micrometers on the metal barrier layer. In the present application, the weldable metal layer 105 has a thickness equal to or less than ⅛ of the typical thickness of the weldable metal layer 305 in the comparative example, thereby greatly reducing the metal usage of the weldable metal layer, which has a significant cost advantage. The interface between the metal wire and the copper surface formed according to the present application has a completely different microscopic morphology from the interface between the metal wire and the copper surface described in the comparative example. FIG. 6 is a scanning electron microscope (SEM) image of a sample of the copper interconnect structure 300 as described. The upper and lower images have different magnifications, and the arrows in the image point to the magnified interface morphology. It can be seen from FIG. 6 that there is obvious delamination at the junction of the aluminum metal wire and the weldable metal layer. And the obvious delamination is very unfavorable for forming low-resistance solder joints. The test results of the corresponding samples also show that the actual resistance test value of the sample is several times higher than the estimated resistance value of the simulation experiment, which cannot meet the mass production requirements.

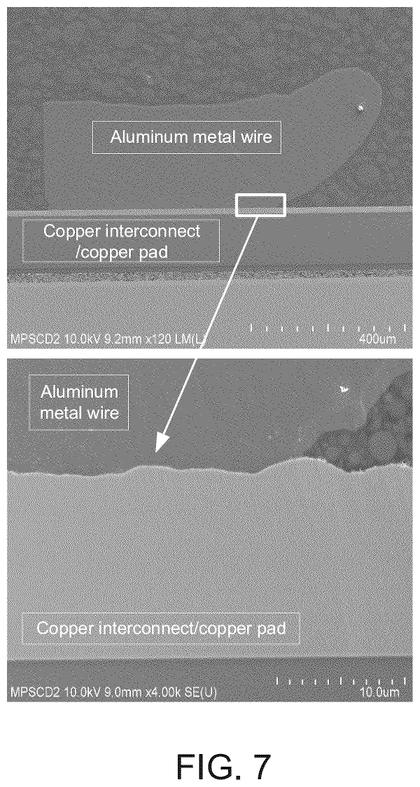

FIG. 7 is a scanning electron microscope image of a sample of the copper interconnect structure 200. The SEM image of the sample of the copper interconnect structure 100 also has this morphology, so it is not shown. In FIG. 7, the upper and lower SEM screenshots have different magnifications, and the arrows in the figure point to the magnified interface morphology. It can be seen from FIG. 7 that the aluminum metal wire and the weldable metal layer are not delaminated at the interface and are tightly bonded, which helps to form a low-resistance, high-bonding-strength solder joint.

Although the present disclosure has been described with reference to several embodiments, it should be understood that the terms used are illustrative and exemplary, rather than for limiting. Since the present disclosure can be implemented in a variety of forms without departing from the spirit or essence of the invention, it should be understood that the above embodiments are not limited to any of the foregoing details, but should be interpreted broadly within the spirit and scope defined by the appended claims. Accordingly, all changes and modifications falling within the scope of the claims or their equivalents should be covered by the appended claims.

What is claimed is:

1. A copper interconnect structure for an integrated circuit chip, comprising:
a copper surface;
a metal barrier layer over the copper surface; and
a weldable metal layer over the metal barrier layer, wherein the weldable metal layer has a thickness ranging from 0.03 micrometers to 0.05 micrometers.

2. The copper interconnect structure of claim 1, wherein the metal barrier layer is made of a material selected from the group consisting of nickel, cobalt, chromium, molybdenum, tungsten and their alloys.

3. The copper interconnect structure of claim 1, wherein the weldable metal layer is made of a material selected from the group consisting of gold, palladium, silver and platinum.

4. The copper interconnect structure of claim 1, further comprising:
a seed metal layer between the copper surface and the metal barrier layer.

5. A bonding structure including a copper interconnect structure for an integrated circuit, the bonding structure comprising:
a copper surface;
a metal barrier layer over the copper surface;
a weldable metal layer over the metal barrier layer; and
a metal wire bonded to the weldable metal layer, wherein the metal wire has a diameter equal to or greater than 125 micrometers.

6. The bonding structure of claim 5, wherein the metal barrier layer is made of a material selected from the group consisting of nickel, cobalt, chromium, molybdenum, tungsten and their alloys.

7. The bonding structure of claim 5, wherein the weldable metal layer is made of a material selected from the group consisting of gold, palladium, silver and platinum.

8. The bonding structure of claim 5, wherein the metal wire comprises aluminum.

9. The bonding structure of claim 5, wherein the metal wire is made of an aluminum metal or an aluminum alloy.

10. A method for fabricating a copper interconnect structure for an integrated circuit chip, the method comprising:
cleaning a copper surface of a non-oxidized copper;
performing a first electroless deposition process to plate a metal barrier layer over the copper surface; and
performing a second electroless deposition process to plate a weldable metal layer over the metal barrier layer, wherein the weldable metal layer has a thickness ranging from 0.03 micrometers to 0.05 micrometers.

11. The method of claim 10, wherein the metal barrier layer is made of a material selected from the group consisting of nickel, cobalt, chromium, molybdenum, tungsten and their alloys.

12. The method of claim 10, wherein the weldable metal layer is made of a material selected from the group consisting of gold, palladium, silver and platinum.

13. A method for bonding a copper interconnect structure of an integrated circuit chip and a metal wire, the method comprising:
cleaning a copper surface of a non-oxidized copper;
performing a first electroless deposition process to plate a metal barrier layer over the copper surface;
performing a second electroless deposition process to plate a weldable metal layer over the metal barrier layer, wherein the weldable metal layer has a thickness ranging from 0.03 micrometers to 0.05 micrometers; and
bonding the metal wire onto the weldable metal layer by pressure welding, wherein the metal wire has a diameter equal to or greater than 125 micrometers.

14. The method of claim 13, wherein the metal barrier layer is made of a material selected from the group consisting of nickel, cobalt, chromium, molybdenum, tungsten and their alloys.

15. The method of claim 13, wherein the weldable metal layer is made of a material selected from the group consisting of gold, palladium, silver and platinum.

16. The method of claim 13, wherein the metal wire comprises aluminum.

17. The method of claim 13, wherein the metal wire is made of an aluminum metal or an aluminum alloy.

18. A copper interconnect structure for an integrated circuit chip, comprising:
a copper pad or a copper redistribution layer;
a metal barrier layer over the copper pad or the copper redistribution layer; and
a weldable metal layer over the metal barrier layer, wherein the weldable metal layer has a thickness ranging from 0.03 micrometers to 0.05 micrometers.
